(19) United States
(12) Patent Application Publication
(10) Pub. No.: US 2009/0073743 A1
(43) Pub. Date: Mar. 19, 2009

(54) Method of Manufacturing a Memory Cell, Memory Cell, Integrated Circuit, and Memory Module

(76) Inventors: Igor Kasko, Dresden (FR); Michael Kund, Tuntenhausen (DE)

Correspondence Address: SLATER & MATSIL, L.L.P., 17950 PRESTON ROAD, SUITE 1000, DALLAS, TX, 75252, US

(21) Appl. No.: 11/856,647

(22) Filed: Sep. 17, 2007

(51) Int. Cl. G11C 11/24; B05D 5/12; C21D 9/00

(52) U.S. Cl. 365/149; 148/559; 427/58

(57) ABSTRACT

A method of fabricating a memory cell including a solid electrolyte layer doped with metallic material and an electrode layer arranged above the solid electrolyte layer. The method includes doping a solid electrolyte layer with metallic material and forming an electrode layer above the solid electrolyte layer, wherein doping the solid electrolyte layer is carried out before forming the electrode layer.

### BRIEF DESCRIPTION OF THE DRAWINGS

For a more complete understanding of exemplary embodiments of the present invention and the advantages thereof, reference is now made to the following description taken in conjunction with the accompanying drawings, in which:

FIG. 1A shows a schematic cross-sectional view of a solid electrolyte memory cell set to a first memory state;

FIG. 1B shows a schematic cross-sectional view of a solid electrolyte memory cell set to a second memory state;

FIGS. 2A to 2D show fabricating stages of a method of fabricating a solid electrolyte memory cell according to one embodiment of the present invention;

FIGS. 3A to 3D show fabricating stages of a method of fabricating a solid electrolyte memory cell according to one embodiment of the present invention;

FIG. 4 shows a method of fabricating a solid electrolyte memory cell according to one embodiment of the present invention;

FIG. 5 shows a method of fabricating a solid electrolyte memory cell according to one embodiment of the present invention;

FIG. 6 shows a method of fabricating a solid electrolyte memory cell according to one embodiment of the present invention;

FIG. 7 shows a method of fabricating a solid electrolyte memory cell according to one embodiment of the present invention;

FIG. 8 shows a method of fabricating a solid electrolyte memory cell according to one embodiment of the present invention;

FIG. 9A shows a memory module according to one embodiment of the present invention; and

FIG. 9B shows a memory module according to one embodiment of the present invention.

### DETAILED DESCRIPTION OF ILLUSTRATIVE EMBODIMENTS

In the following description, it will be assumed that the memory cell is a solid electrolyte memory cell/solid electrolyte memory device. However, the invention is not restricted thereto. The principles underlying the following may also be applied to other types of memory cells/memory devices.

According to one embodiment of the present invention, a method of manufacturing a solid electrolyte memory cell is provided, the solid electrolyte memory cell including a metallic material doped solid electrolyte layer and an electrode layer being arranged above the solid electrolyte layer. The method includes the processes of doping a solid electrolyte layer with metallic material using a thermal dissolution process, and depositing an electrode layer above the solid electrolyte layer, wherein doping the solid electrolyte layer is carried out before deposition of the electrode layer.

Normally, the electrode layer is deposited on the solid electrolyte layer before carrying out the doping process since the electrode layer is used as a doping material source when doping the solid electrolyte layer: that is, the doping process is carried out by subjecting the electrode layer to an annealing process which causes doping material to diffuse out of the electrode layer into the solid electrolyte layer. In contrast, according to the embodiment mentioned above, the electrode layer is deposited after having carried out the doping process, i.e. the electrode layer is not used as a doping source. By “separating” the process of doping the solid electrolyte layer from the process of forming the electrode layer, the process of doping the solid electrolyte layer can be carried out with improved precision.

According to one embodiment of the present invention, the process of doping the solid electrolyte layer is performed by carrying out the following sequence of processes at least once: Depositing a doping layer comprising metallic doping material on the solid electrolyte layer, and subjecting the doping layer to a thermal dissolution process, thereby causing metallic doping material to diffuse into the solid electrolyte layer.

In this embodiment, it is possible to “replace” a single thick doping layer (for example an electrode layer also functioning as a metallic doping material source) by several thin doping layers. An effect of such a replacement is that the concentration of metallic doping material within the solid electrolyte layer can be adjusted with high precision.

According to one embodiment of the present invention, the thickness of the doping layers and/or the parameters of the thermal dissolution processes are chosen such that after each annealing process a uniformly doped solid electrolyte layer is obtained.

According to one embodiment of the present invention, the total amount of metallic doping material diffusing into the solid electrolyte layer is adjusted by varying the thicknesses of the doping layers and/or the parameters of the thermal dissolution processes and/or the total amount/concentration of metallic doping material included within the doping layers.

According to one embodiment of the present invention, at least one annealing process is carried out such that the whole metallic doping material included within the corresponding doping layer diffuses into the solid electrolyte layer.

According to one embodiment of the present invention, the electrolyte layer includes electrode material that is the same material as the metallic doping material, wherein the concentration level of the electrode material within the electrode layer is the same as or close to the concentration level of the metallic doping material within the doped solid electrolyte layer.

According to one embodiment of the present invention, the doping layers include or consist of alloys.

According to one embodiment of the present invention, the solid electrolyte layer includes or consists of chalcogenide material.

According to one embodiment of the present invention, the thicknesses of the doping layers ranges between about 10 nm to about 15 nm or less.

According to one embodiment of the present invention, the annealing temperature during the annealing processes ranges between about 250° C. and about 350° C.

According to one embodiment of the present invention, the durations of the annealing processes range between about 10 minutes to about 30 minutes.

According to one embodiment of the present invention, the doping of the solid electrolyte layer is carried out such that the concentration of the metallic doping material within the solid electrolyte layer material is about 30% to about 35%.

According to one embodiment of the present invention, the concentration of the metallic doping material within the doping layers ranges between about 60% to about 100%.

According to one embodiment of the present invention, the concentration of the metallic doping material within the doping layers is about 80%.

According to one embodiment of the present invention, the doping layers comprise or consist of silver (Ag).

According to one embodiment of the present invention, the doping layers comprise or consist of AgTa.

According to one embodiment of the present invention, the thicknesses of the solid electrolyte layer is about 50 nm.

According to one embodiment of the present invention, the sum of the thicknesses of all doping layers used for doping one solid electrolyte layer is about 30 nm.

According to one embodiment of the present invention, a method of fabricating a solid electrolyte memory cell is provided, the solid electrolyte memory cell including a doped solid electrolyte layer and an electrode layer being arranged above the solid electrolyte layer. The method includes a process of doping a solid electrolyte layer using a photo dissolution process, and a process of forming an electrode layer above the solid electrolyte layer, wherein the process of doping the solid electrolyte layer is carried out before the process of forming the electrode layer.

According to one embodiment of the present invention, the process of doping the solid electrolyte layer is performed by carrying out at least once the following processes: Depositing a doping layer comprising metallic doping material above the solid electrolyte layer, and carrying out a photo dissolution process, thereby causing metallic doping material to diffuse into the solid electrolyte layer.

According to one embodiment of the present invention, the thickness of the doping layers and/or the parameters of the photo dissolution processes are chosen such that after each photo dissolution process a uniformly doped solid electrolyte layer is obtained.

According to one embodiment of the present invention, the total amount of metallic doping material diffusing into the solid electrolyte layer is adjusted by varying the thicknesses of the doping layers and/or the parameters of the photo dissolution processes and/or the total amount/concentration of metallic doping material included within the doping layers.

According to one embodiment of the present invention, at least one photo dissolution process is carried out such that the whole metallic doping material included within the corresponding doping layer diffuses into the solid electrolyte layer.

According to one embodiment of the present invention, the electrode layer includes electrode material that is the same material as the metallic doping material, wherein the concentration level of the electrode material within the electrode layer is the same as or close to the concentration level of the metallic doping material within the doped solid electrolyte layer.

According to one embodiment of the present invention, the doping layers include or consist of alloys.

According to one embodiment of the present invention, the solid electrolyte layers include or consist of chalcogenide material.

According to one embodiment of the present invention, at least one annealing process is carried out during or after at least one photo dissolution process.

According to one embodiment of the present invention, the thicknesses of the doping layers are about 10 nm or less.

According to one embodiment of the present invention, the photo dissolution processes are carried out using about 115 mW/cm² and a wavelength of about 405 nm.

According to one embodiment of the present invention, the exposure durations of the photo dissolution processes are about 20 minutes.

According to one embodiment of the present invention, the total irradiating dose is about 140 J/cm².

According to one embodiment of the present invention, doping the solid electrolyte layer is carried out such that the concentration of the metallic doping material within the solid electrolyte layer material is about 30% to about 35%.

According to one embodiment of the present invention, the concentration of the metallic doping material within the doping layers ranges between about 60% to about 100%.

According to one embodiment of the present invention, the concentration of the metallic doping material within the doping layers is about 80%.

According to one embodiment of the present invention, the doping layers comprise or consist of AgTa.

According to one embodiment of the present invention, the solid electrolyte layer comprises or consists of chalcogenide material.

According to one embodiment of the present invention, the thickness of the solid electrolyte layer is about 50 nm.

According to one embodiment of the present invention, the sum of the thicknesses of the doping layers used is about 30 nm.

According to one embodiment of the present invention, a method of fabricating a solid electrolyte memory cell is provided. The solid electrolyte memory cell includes a doped solid electrolyte layer and an electrode layer arranged on the solid electrolyte layer. The method includes the process of doping a solid electrolyte layer, and a process of forming an electrode layer on the solid electrolyte layer, wherein doping the solid electrolyte layer is carried out before forming the electrode layer.

Within the scope of the present invention, the term “forming an electrode layer above the solid electrolyte layer” includes both providing the electrode layer directly on the solid electrolyte layer and providing a composite structure on the solid electrolyte layer including an electrode layer and an intermediate layer disposed between the electrode layer and the solid electrolyte layer. Further, more than one intermediate layer may be provided between the electrode layer and the solid electrolyte layer.

After having carried out the deposition of the electrode layer, the solid electrolyte memory cell may be finalized by carrying out a typical back end of line process (e.g., deposition of several metal layers, isolation layers, passivation layers, etc.).

According to one embodiment of the present invention, a solid electrolyte memory cell is provided including a solid electrolyte layer doped with metallic doping material, and an electrode layer arranged above the solid electrolyte layer. The electrode layer includes electrode material that is the same material as the metallic doping material (for example silver (Ag) material). The concentration level of the electrode material within the electrode layer is the same as or close to the concentration level of the metallic doping material within the doped solid electrolyte layer.

According to one embodiment of the present invention, an integrated circuit including at least one memory cell is provided. The memory cell including: a solid electrolyte layer doped with metallic doping material, and an electrode layer arranged above the solid electrolyte layer. The electrode layer includes electrode material that is the same material as the metallic doping material, the concentration level of the electrode material within the electrode layer being the same as or close to the concentration level of the metallic doping material within the metallic material doped solid electrolyte layer.

According to one embodiment of the present invention, a memory module including at least one integrated circuit including at least one memory cell is provided. The memory cell includes a solid electrolyte layer doped with metallic doping material, and an electrode layer arranged above the solid electrolyte layer. The electrode layer includes electrode material that is the same material as the metallic doping material, the concentration level of the electrode material within the electrode layer being the same as or close to the concentration level of the metallic doping material within the metallic material doped solid electrolyte layer.

According to one embodiment of the present invention, the memory module is stackable.

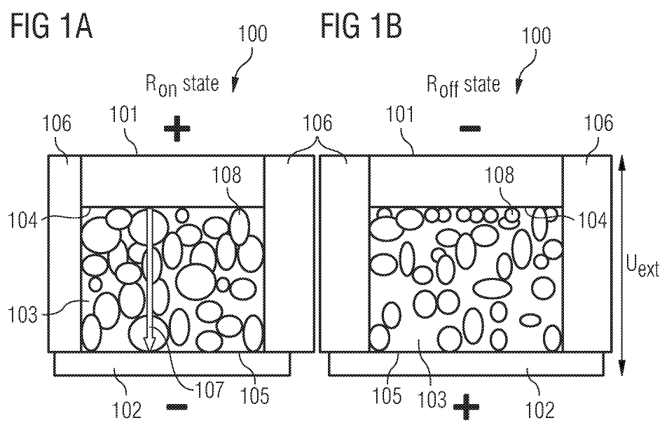

Since the embodiments of the present invention can be applied to programmable metallization cell devices (PMC) (e.g. solid electrolyte devices like CBRAM (conductive bridging random access memory) devices), in the following description, making reference to FIGS. 1A and 1B, a basic principle underlying embodiments of CBRAM devices will be explained.

As shown in FIG. 1A, a CBRAM cell 100 includes a first electrode 101, a second electrode 102, and a solid electrolyte block (in the following also referred to as an ion conductor block) 103, which includes the active material and which is sandwiched between the first electrode 101 and the second electrode 102. This solid electrolyte block 103 can also be shared between a large number of memory cells (not shown here). The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, the second surface 105 the bottom surface of the ion conductor block 103. In the same way, the first electrode 101 generally is the top electrode, and the second electrode 102 the bottom electrode of the CBRAM cell. One of the first electrode 101 and the second electrode 102 is a reactive electrode, the other one an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂. The present invention is however not restricted to these materials. For example, the first electrode 101 may alternatively or additionally include copper (Cu) or zink (Zn), and the ion conductor block 103 may alternatively or additionally include copper-doped chalcogenide material. Further, the second electrode 102 may alternatively or additionally include nickel (Ni), platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned compounds, and can also include alloys of the aforementioned metals or materials. The thickness of the ion conductor block 103 may for example range between about 5 nm and about 500 nm. The thickness of the first electrode 101 may for example range between about 10 nm and about 100 nm. The thickness of the second electrode 102 may for example range between about 5 nm and about 500 nm, between about 15 nm to about 150 nm, or between about 25 nm and about 100 nm. It is to be understood that the present invention is not restricted to the above-mentioned materials and thicknesses.

In the context of this description, chalcogenide material (ion conductor) is to be understood for example as any compound containing oxygen, sulphur, selenium, germanium and/or tellurium. In accordance with one embodiment of the invention, the ion conducting material is for example a compound, which is made of a chalcogenide and at least one metal of the group I or group II of the periodic system, for example arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, that is selected from a group consisting of silver, copper and zinc or of a combination or an alloy of these metals.

If a voltage as indicated in FIG. 1A is applied across the ion conductor block 103, a redox reaction is initiated which drives Ag⁺ ions out of the first electrode 101 into the ion conductor block 103 where they are reduced to Ag, thereby forming Ag rich clusters 108 within the ion conductor block 103. If the voltage applied across the ion conductor block 103 is applied for an enhanced period of time, the size and the number of Ag rich clusters within the ion conductor block 103 is increased to such an extent that a conductive bridge 107 between the first electrode 101 and the second electrode 102 is formed. If a voltage is applied across the ion conductor block 103 as shown in FIG. 1B (inverse voltage compared to the voltage applied in FIG. 1A), a redox reaction is initiated which drives Ag⁺ ions out of the ion conductor block 103 into the first electrode 101 where they are reduced to Ag. As a consequence, the size and the number of Ag rich clusters 108 within the ion conductor block 103 is reduced, thereby erasing the conductive bridge 107. After having applied the voltage/inverse voltage, the memory cell 100 remains within the corresponding defined switching state even if the voltage/inverse voltage has been removed.

In order to determine the current memory status of a CBRAM cell, for example a sensing current is routed through the CBRAM cell. The sensing current experiences a high resistance when no conductive bridge 107 exists within the CBRAM cell, and experiences a low resistance when a conductive bridge 107 exists within the CBRAM cell. A high resistance may for example represent “0”, whereas a low resistance represents “1”, or vice versa. The memory status detection may also be carried out using sensing voltages.

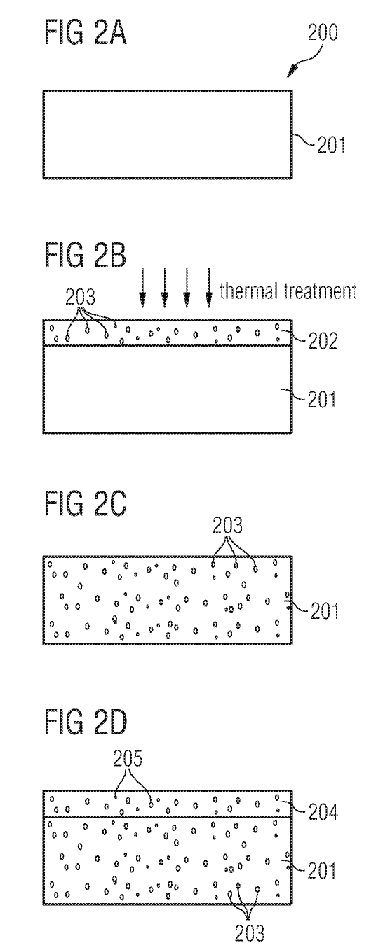

In the following description, making reference to FIGS. 2A to 2D, a method 200 of fabricating a solid electrolyte memory cell according to one embodiment of the present invention will be described.

FIG. 2A shows a fabricating stage in which a solid electrolyte layer 201 has been provided. The solid electrolyte layer 201 may for example include or consist of chalcogenide material like germanium sulfide (GeS).

FIG. 2B shows a fabricating stage in which a doping layer 202 has been provided on the solid electrolyte layer 201. The doping layer 202 includes or consists of metallic doping material 203 like silver (Ag) or an alloy including the metallic doping material 203. After having provided the doping layer 202 on the solid electrolyte layer 201, the doping layer 202 is subjected to a thermal dissolution process (annealing process) which causes the metallic doping material 203 to diffuse into the solid electrolyte layer 201 as indicated in a fabricating stage shown in FIG. 2C. Here, it is assumed that the doping layer 202 consists of metallic doping material 203 and that the thickness of the doping layer 202 is very thin. As a consequence, the whole metallic doping material 203 diffuses into the solid electrolyte layer 202, i.e. the doping layer 202 “disappears”. In this way, the solid electrolyte layer 201 is doped with the metallic doping material 203.

In the fabricating stage shown in FIG. 2D, an electrode layer 204 is provided on the doped solid electrolyte layer 201. Here, the electrode layer 204 includes or consists of electrode material 205 which is the same material as the metallic doping material 203 (for example silver). The concentration of the electrode material 205 within the electrode layer 204 may be the same concentration as the concentration of the metallic doping material 203 within the doping layer 202. In this way, it is ensured that high temperatures occurring in the further processing of the solid electrolyte memory cell (back end of line process) do not influence the concentration profile of the metallic doping material 203 within the solid electrolyte layer 201.

The thickness of the doping layer 202 and/or the thickness of the solid electrolyte layer 201 and/or the concentration of the metallic doping material 203 within the doping layer 202 and/or the duration and the temperature of the thermal dissolution process may be chosen such that a uniform concentration profile of metallic doping material 203 within the solid electrolyte layer 201 is obtained.

The fabricating stages shown in FIGS. 2B and 2C may be repeated, i.e. several doping layers 202 may be deposited, wherein after each depositing process an annealing process (thermal dissolution process) is carried out. In this way, each annealing process increases the level of concentration of metallic doping material 203 within the solid electrolyte layer 201. In this way, it is possible to adjust the concentration level of metallic doping material 203 within the solid electrolyte layer 201 very precisely to arbitrary levels. An effect of this fabricating strategy is that the thickness of the doping layers 202 can be kept very small. As a consequence, problems occurring in conjunction with very thick doping layers (non-uniform concentration profiles of metallic doping material 203 within the doping layer 202) can be avoided.

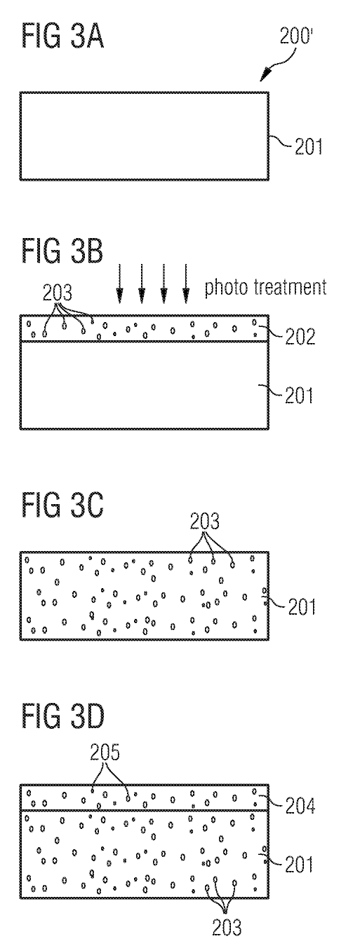

In the following description, making reference to FIGS. 3A to 3D, a method 200′ of fabricating a solid electrolyte memory cell according to one embodiment of the present invention will be described.

FIG. 3A shows a fabricating stage in which a solid electrolyte layer 201 has been provided. FIG. 3B shows a fabricating stage in which a doping layer 202 has been provided on the solid electrolyte layer 201. The doping layer 202 includes or consists of metallic doping material 203 like silver (Ag) or an alloy including the metallic doping material 203.

After having provided the doping layer 202 on the solid electrolyte layer 201, the doping layer 202 is subjected to a photo dissolution process (and optionally to at least one annealing process) which causes the metallic doping material 203 to diffuse into the solid electrolyte layer 201 as indicated in a fabricating stage shown in FIG. 3C. Here, it is assumed that the doping layer 202 consists of metallic doping material 203 and that the thickness of the doping layer 202 is very thin. As a consequence, the whole metallic doping material 203 diffuses into the solid electrolyte layer 202, i.e. the doping layer 202 “disappears”. In this way, the solid electrolyte layer 201 is doped with the metallic doping material 203.

In the fabricating stage shown in FIG. 3D, an electrode layer 204 is provided on the doped solid electrolyte layer 201. Here, the electrode layer 204 includes or consists of electrode material 205 which is the same material as the metallic doping material 203 (for example silver). The concentration of the electrode material 205 within the electrode layer 204 may be the same concentration as the concentration of the metallic doping material 203 within the doping layer 202. In this way, it is ensured that high temperatures occurring in the further processing of the solid electrolyte memory cell (back end of line process) do not influence the concentration profile of the metallic doping material 203 within the solid electrolyte layer 201.

The thickness of the doping layer 202 and/or the thickness of the solid electrolyte layer 201 and/or the concentration of the metallic doping material 203 within the doping layer 202 and/or the duration and strength of the thermal dissolution process may be chosen such that an uniform concentration profile of metallic doping material 203 within the solid electrolyte layer 201 is obtained.

The fabricating stages shown in FIGS. 3B and 3C may be repeated, i.e. several doping layers 202 may be deposited, wherein after each depositing process a photo dissolution process (and optionally an annealing process) is carried out. In this way, each photo dissolution process increases the level of concentration of metallic doping material 203 within the solid electrolyte layer 201. In this way, it is possible to adjust the concentration level of metallic doping material 203 within the solid electrolyte layer 201 very precisely to arbitrary levels. An effect of this fabricating strategy is that the thickness of the doping layers 202 can be kept very small. As a consequence, problems occurring in conjunction with very thick doping layers (non-uniform concentration profiles of metallic doping material 203 within the doping layer 202) can be avoided.

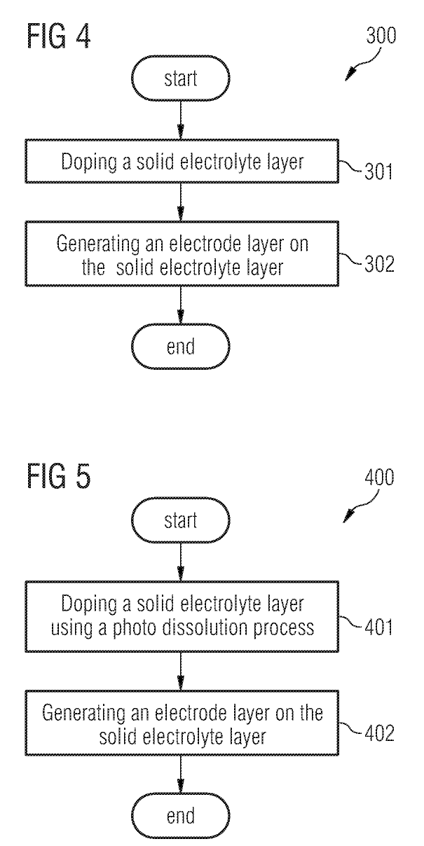

FIG. 4 shows a method 300 of fabricating a solid electrolyte memory cell according to one embodiment of the present invention. In a first process 301, a solid electrolyte layer is doped with metallic doping material. In a second process 302, an electrode layer is provided on the solid electrolyte layer.

FIG. 5 shows a method 400 of fabricating a solid electrolyte memory cell according to one embodiment of the present invention. In a first process 401, a solid electrolyte layer is doped with metallic doping material using a photo dissolution process. In a second process 402, an electrode layer is provided on the solid electrolyte layer.

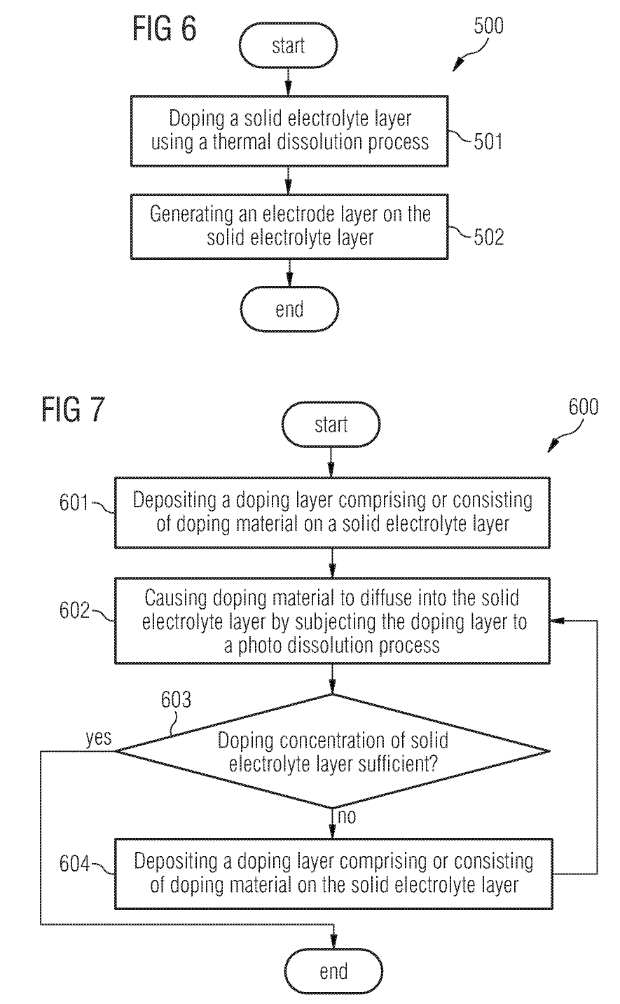

FIG. 6 shows a method 500 of fabricating a solid electrolyte memory cell according to one embodiment of the present invention. The method includes a first process 501 of doping a solid electrolyte layer using a thermal dissolution process and a second process 502 of providing an electrode layer on the solid electrolyte layer.

FIG. 7 shows a method 600 of fabricating a solid electrolyte memory cell according to one embodiment of the present invention which method includes the following processes: in a first process 601, a doping layer including or consisting of metallic doping material is deposited on a solid electrolyte layer. In a second process 602, the metallic doping material is caused to diffuse into the solid electrolyte layer by subjecting the doping layer to a photo dissolution process. In a third process 603, it is determined whether the doping concentration of the solid electrolyte layer already matches a predetermined doping concentration target value. If this is the case, the doping process is terminated. Otherwise, in a fourth process 604, a doping layer including or consisting of metallic doping material is deposited on the solid electrolyte layer. Then, the method returns to the second process 602. The second to fourth processes 602 to 604 are carried out until the doping concentration of the solid electrolyte layer matches the doping concentration target value.

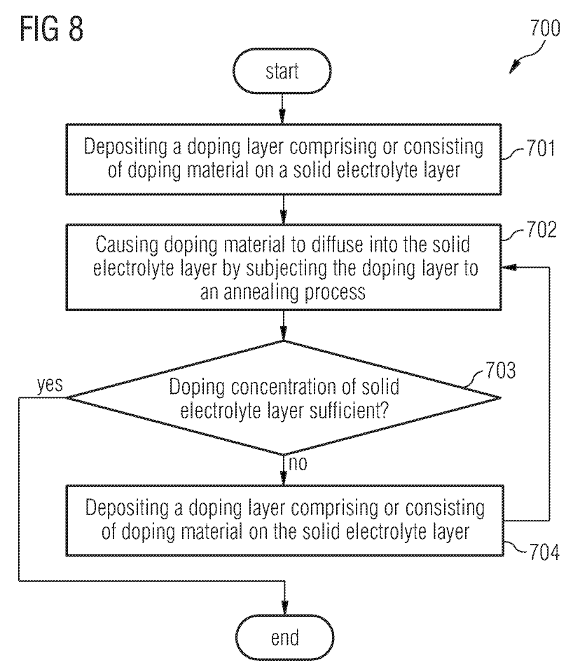

FIG. 8 shows a method 700 of fabricating a solid electrolyte memory cell according to one embodiment of the present invention which method includes the following processes: In a first process 701, a doping layer including or consisting of metallic doping material is deposited on a solid electrolyte layer. In a second process 702, the metallic doping material is caused to diffuse into the solid electrolyte layer by subjecting the doping layer to a thermal dissolution process. In a third process 703, it is determined whether the doping concentration of the solid electrolyte layer already matches a predetermined doping concentration target value. If this is the case, the doping process is terminated. Otherwise, in a fourth process 704, a doping layer including or consisting of metallic doping material is deposited on the solid electrolyte layer. Then, the method returns to the second process 702. The second to fourth processes 702 to 704 are carried out until the doping concentration of the solid electrolyte layer matches the doping concentration target value.

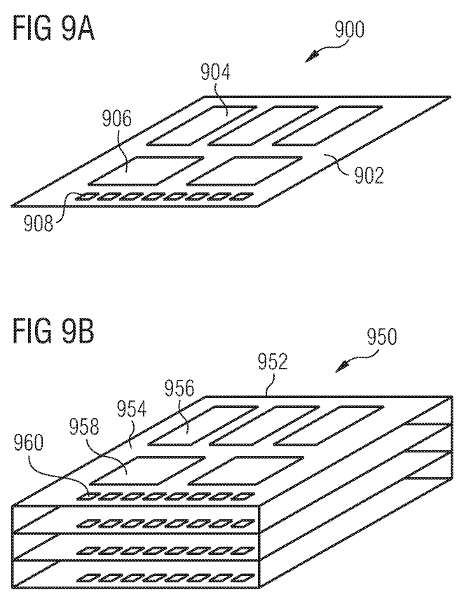

As shown in FIGS. 9A and 9B, in some embodiments, memory cells such as those described herein may be used in modules. In FIG. 9A, a memory module 900 is shown, on which one or more memory cells 904 are arranged on a substrate 902. The memory module 900 may also include one or more electronic devices 906, which may include memory, processing circuitry, control circuitry, addressing circuitry, bus interconnection circuitry, or other circuitry or electronic devices that may be combined on a module with a memory device, such as the memory cells 904. Additionally, the memory module 900 includes multiple electrical connections 908, which may be used to connect the memory module 900 to other electronic components, including other modules.

As shown in FIG. 9B, in some embodiments, these modules may be stackable, to form a stack 950. For example, a stackable memory module 952 may contain one or more memory devices 956 arranged on a stackable substrate 954. The memory device 956 contains memory cells in accordance with an embodiment of the invention. The stackable memory module 952 may also include one or more electronic devices 958, which may include memory, processing circuitry, control circuitry, addressing circuitry, bus interconnection circuitry, or other circuitry or electronic devices that may be combined on a module with a memory device, such as the memory device 956. Electrical connections 960 are used to connect the stackable memory module 952 with other modules in the stack 950, or with other electronic devices. Other modules in the stack 950 may include additional stackable memory modules, similar to the stackable memory module 952 described above, or other types of stackable modules, such as stackable processing modules, control modules, communication modules, or other modules containing electronic components.

In the following description, further aspects of the present invention will be explained.

According to one embodiment of the present invention, it is possible to better control the doping process of a solid electrolyte memory device (e.g. better control of the doping level and the doping profile of a CBRAM stack with silver (Ag)). Further, according to one embodiment of the present invention, the thermal stability of the solid electrolyte memory device (e.g. CBRAM stack) is enhanced.

There are two main approaches for silver dissolution in chalcogenide materials: silver photo dissolution and silver thermal dissolution. Compared to silver thermal dissolution, silver photo dissolution has the effect that a better microstructure is obtained since the formation of large silver rich clusters and their crystallization is prevented.

However, the silver photo dissolution method, as currently used, has several limitations:
the solver thickness has to be adjusted due to light absorption;
the doping of thicker chalcogenide layers is limited due to silver thickness limitations;
it is difficult to control the doping level; and
the silver dissolution from a silver electrode in contact with the chalcogenide material may continue during subsequent manufacturing steps (thermal stress, plasma exposure, etc.) resulting in a modification (or even in a degradation) of CBRAM cell properties.

According to one embodiment of the present invention, a CBRAM stack fabrication is divided into two main processes: a) chalcogenide doping, and b) Ag electrode fabrication.

According to one embodiment of the present invention, the chalcogenide doping is carried out by Ag photo dissolution, which is realized as a multi step process consisting of a sequence of Ag deposition and photo dissolution. The Ag thickness and photo dissolution parameters are adjusted such that a full and uniform Ag dissolution in the chalcogenide film is achieved. The step by step doping improves the doping uniformity and prevents formation of Ag extrusions. The final Ag concentration can be easily controlled by the total amount of deposited Ag. According to one embodiment of the present invention, instead of pure Ag deposition, Ag alloys are used in order to provide better film morphology during a film deposition process. The effectiveness of the photo dissolution process may also be enhanced by the combination with thermal anneal during or after the photo dissolution steps.

According to one embodiment of the present invention, in order to fabricate the Ag electrode, an Ag alloy is used which has an Ag concentration level close to the Ag concentration level in the doped chalcogenide material. The same concentration level of Ag in both materials prevents the formation of a Ag concentration gradient, and thus will also prevent the Ag diffusion from the Ag electrode to the Ag doped chalcogenide during subsequent processing. This effect will improve the thermal stability of the CBRAM cell.

Effects of embodiments of the present invention are:
it is possible to better control the Ag concentration in the chalcogenide material;
it is possible to uniformly dope the chalcogenide material;
it is possible to dope thicker chalcogenide films for improved functionality (Ag amount is not limited by optically transparent Ag film requirement as in other methods); and
an improved cell thermal stability can be achieved by the fabrication of the top electrode with a predefined Ag concentration.

According to one embodiment of the present invention, the doping process and the electrode fabrication processes are separated.

According to one embodiment of the present invention, a multi step doping process of chalcogenide is carried out ((very) thin Ag film deposition/photo dissolution for complete Ag dissolution).

According to one embodiment of the present invention, a thermally assisted enhanced Ag dissolution (during or post photo dissolution steps) is carried out.

According to one embodiment of the present invention, the electrode is fabricated with an Ag concentration close to the Ag concentration level in the chalcogenide.

The thermal doping of chalcogenide material in the CBRAM stack may be controlled by the design of the multi layer stack (Ag or Ag-alloy electrode in contact with chalcogenide) and by anneal conditions of the multi layer stack. The Ag containing electrode layer is used as an Ag source for chalcogenide doping and as an electrode to provide the CBRAM cell functionality. Disadvantages of this approach are:
the doping of chalcogenide does occur from the unlimited Ag source (i.e. it is difficult to control the maximum Ag concentration; thus, a high Ag concentration gradient may result in local over saturation and crystallization); and
the Ag dissolution process may continue during subsequent wafer processing resulting in a modification (or even degradation) of CBRAM cell properties.

According to one embodiment of the present invention, these disadvantages are overcome by separating the CBRAM stack fabrication into two main steps: a) chalcogenide doping, and b) Ag electrode fabrication:

a) The chalcogenide doping is carried out by using a thermal Ag dissolution which is realized as a multi step process consisting of a sequence of Ag deposition and thermal anneal. The Ag thickness and anneal are adjusted in order to achieve a full and uniform Ag dissolution in the chalcogenide film. The step by step doping improves the doping uniformity and prevents formation of Ag extrusions. The final Ag concentration can be easily controlled by the total amount of deposited Ag. Instead of pure Ag deposition, Ag alloys may be used in order to provide better film morphology during the film deposition process; and

b) In order to fabricate the Ag electrode, an Ag alloy is used having an Ag concentration level close to the Ag concentration level of the chalcogenide material. The same concentration level of Ag in both materials prevents the formation of the Ag concentration gradient, and thus will also prevent the Ag diffusion from the electrode to chalcogenide during subsequent processing. This effect will improve the thermal stability of the CBRAM cell.

The embodiments described above have been described in the context of electrodes comprising silver and chalcogenide comprising silver. It is to be understood that the present invention is not restricted to these materials/elements. Arbitrary suitable materials may be used to realize the same effects.

As used herein, the terms “connected” and “coupled” are intended to include both direct and indirect connection and coupling, respectively.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. A method of manufacturing a memory cell, the method comprising:
doping a solid electrolyte layer with metallic doping material using a thermal dissolution process; and
depositing an electrode layer above the solid electrolyte layer, wherein doping the solid electrolyte layer is carried out before depositing the electrode layer.

2. The method according to claim 1, wherein doping the solid electrolyte layer is performed by carrying out the following sequence of processes at least twice:
depositing a doping layer comprising metallic doping material above the solid electrolyte layer; and
subjecting the doping layer to the thermal dissolution process, thereby causing the metallic doping material to diffuse into the solid electrolyte layer.

3. The method according to claim 2, wherein thicknesses of the doping layers and parameters of the thermal dissolution processes are chosen such that after an annealing process a uniformly metallic material doped solid electrolyte layer is obtained.

4. The method according to claim 2, wherein a total amount of metallic doping material diffusing into the solid electrolyte layer is adjusted by varying thicknesses of the doping layers, parameters of the thermal dissolution processes and a total amount of metallic doping material included within the doping layers.

5. The method according to claim 2, wherein at least one annealing process is carried out such that the whole metallic doping material included within the corresponding doping layer diffuses into the solid electrolyte layer.

6. The method according to claim 2, wherein thicknesses of the doping layers range between 10 nm to 15 nm.

7. The method according to claim 2, wherein an annealing temperature during annealing processes ranges between 250° C. and 350° C.

8. The method according to claim 2, wherein durations of annealing processes range between 10 min to 30 min.

9. The method according to claim 2, wherein doping the solid electrolyte layer is carried out such that a concentration of the metallic doping material within the solid electrolyte layer material is 30% to 35%.

10. The method according to claim 2, wherein a concentration of the metallic doping material within the doping layers ranges between 60% to 100%.

11. The method according to claim 2, wherein a concentration of the metallic doping material within the doping layers is about 80%.

12. The method according to claim 2, wherein the electrode layer comprises electrode material that is a same material as the metallic doping material, wherein a concentration level of the electrode material within the electrode layer is the same as or close to a concentration level of the metallic doping material within the doped solid electrolyte layer.

13. A method of fabricating a memory cell, the method comprising:
doping a solid electrolyte layer with metallic doping material using a photo dissolution process; and
forming an electrode layer above the solid electrolyte layer, wherein doping the solid electrolyte layer is carried out before forming of the electrode layer.

14. The method according to claim 13, wherein doping the solid electrolyte layer is performed by carrying out the following sequence of processes at least twice:
depositing a doping layer comprising metallic doping material above the solid electrolyte layer; and
carrying out the photo dissolution process, thereby causing the metallic doping material to diffuse into the solid electrolyte layer.

15. The method according to claim 14, wherein thicknesses of the doping layers and parameters of the photo dissolution processes are chosen such that after each photo dissolution process a uniformly metallic material doped solid electrolyte layer is obtained.

16. The method according to claim 14, wherein a total amount of metallic doping material diffusing into the solid electrolyte layer is adjusted by varying thicknesses of the doping layers, parameters of the photo dissolution processes and a total amount of metallic doping material included within the doping layers.

17. The method according to claim 14, wherein at least one photo dissolution process is carried out such that the whole metallic doping material included within the corresponding doping layer diffuses into the solid electrolyte layer.

18. The method according to claim 14, wherein the electrode layer comprises electrode material that is a same material as the doping material, wherein a concentration level of the electrode material within the electrode layer is the same as or close to a concentration level of the metallic doping material within the metallic material doped solid electrolyte layer.

19. The method according to claim 14, wherein the doping layers comprise alloys.

20. The method according to claim 14, wherein the solid electrolyte layers comprise chalcogenide material.

21. The method according to claim 14, wherein at least one annealing process is carried out during or after at least one photo dissolution process.

22. The method according to claim 14, wherein the doping layers have a thickness of about 10 nm.

23. A method of fabricating a memory cell comprising a metallic material doped solid electrolyte layer and an electrode layer arranged above the solid electrolyte layer, the method comprising:
doping the solid electrolyte layer with metallic doping material; and
forming the electrode layer above the solid electrolyte layer, wherein doping the solid electrolyte layer is carried out before forming the electrode layer.

24. A memory cell comprising:
a solid electrolyte layer doped with metallic doping material; and
an electrode layer arranged above the solid electrolyte layer, the electrode layer comprising electrode material that is a same material as the metallic doping material,
wherein a concentration level of the electrode material within the electrode layer is the same as or close to a concentration level of the metallic doping material within the metallic material doped solid electrolyte layer.

25. An integrated circuit comprising at least one memory cell, the integrated circuit comprising:
a solid electrolyte layer doped with metallic doping material; and
an electrode layer arranged above the solid electrolyte layer, the electrode layer comprising electrode material that is a same material as the metallic doping material,
wherein a concentration level of the electrode material within the electrode layer is the same as or close to a concentration level of the metallic doping material within the metallic material doped solid electrolyte layer.
